(19) United States
(12) Patent Application Publication
(10) Pub. No.: US 2015/0236082 A1
(43) Pub. Date: Aug. 20, 2015

(54) DUAL-SIDE DISPLAY, DEVICE FOR CONTROLLING THE DUAL-SIDE DISPLAY AND METHOD FOR MANUFACTURING THE SAME

(71) Applicant: EverDisplay Optronics (Shanghai) Limited, Shanghai (CN)

(72) Inventors: Meilin WANG, Shanghai (CN); Peiming CHU, Shanghai (CN); Zhaobin YANG, Shanghai (CN)

(21) Appl. No.: 14/445,932

(22) Filed: Jul. 29, 2014

(30) Foreign Application Priority Data
Feb. 14, 2014 (CN) 201410051852.3

(51) Int. Cl. H01L 27/32; H01L 51/56

(52) U.S. Cl. CPC H01L 27/3267; H01L 27/3258; H01L 27/3232; H01L 51/56; H01L 2227/323

(57) ABSTRACT

A dual-side display including an OLED substrate, a package substrate located at opposite side of the OLED substrate and frit seal sandwiched between the OLED substrate and the package substrate, wherein, the package substrate is an electrophoresis membrane, the part of the electrophoresis membrane that does not cover the OLED substrate is configured to display at one surface of the dual-side display, the OLED substrate is configured to display at another surface opposite to the one surface of the dual-side display. According to the dual-side display of the application, the dual-side display can effectively increase the light emitting area of the OLED, as well as the aperture ration and the display luminance of the OLED display panel, and achieves dual-side display to satisfy different requirements. Besides, the OLED display of the present application can make full use of light-emitting pixel area and obtain better light emitting effect.

### CROSS-REFERENCE TO RELATED APPLICATIONS

This application claims the benefit of Chinese Patent Application No. 201410051852.3 filed on Feb. 14, 2014 in the State Intellectual Property Office of China, the application of which is incorporated herein by reference in its entirety.

### TECHNICAL FIELD

The present application relates in general to a dual-side display, a device for controlling the dual-side display and the method for manufacturing the same.

### BACKGROUND ART

OLED display is a solid-state device formed by thin organic molecule layers which can emit light after voltage is applied. OLED displays usually have a sandwich structure, that is, an organic layer is sandwiched between two electrodes. Electron hole and electron are injected from anode and cathode, respectively, transmit in an organic layer, meet each other, form exciton and emit light. The anode is a transparent electrode made of ITO (Indium Tin Oxide), so that it can transmit light. The cathode is usually made of low work function metal such as Magnesium (Mg) or Lithium (Li). OLED display can provide electronic device a brighter and clearer image, and it has lower power consumption than the conventional LED display screen. As a result, the OLED display has advantages as below: compared with crystal layers of the conventional LED or LCD display, the organic molecule layer of OLED is thinner, lighter and more flexible; the OLED display screen is made of self-emissive material instead of using a back light plate, and it has wide visual angle, uniform image quality, fast response speed, high colorize capability. Besides, it can emit light employing simple driving circuit, has simple manufacturing process, can be made of flexible panel and meets the requirement of being slim, thin, short and small.

FIG. 1 is a schematic sectional diagram showing a conventional OLED display device 1′ which is a bottom emission type OLED display device. In FIG. 1, reference numeral 10′ represents an OLED substrate, OLED lighting devices and active matrix TFTs (thin film transistor) are disposed on the OLED substrate 10′. The OLED substrate 10′ is made of rigid or flexible material. Reference numeral 20′ represents a package substrate, the package substrate 20′ is usually made of rigid material such as glass, or flexible membrane package formed by organic membrane and inorganic membrane stacked on top of each other. Frit seal 30′ is disposed between the OLED substrate 10′ and the package substrate 20′ of the OLED display device 1′, the frit seal 30′ is used to fix and connect the OLED substrate 10′ and the package substrate 20′. The surface indicated by arrow in FIG. 1 is the light emitting surface of the OLED display device 1′.

FIG. 2 is a schematic diagram showing a pixel plane in the conventional OLED display device. In FIG. 2, three sub-pixels are shown. The area shown by reference numeral 21′ is a blank area, the area shown by reference numeral 22′ is actual pixel light-emitting area. As shown in FIG. 2, due to the affect of the OLED evaporation accuracy, the light-emitting area of the conventional OLED display device is very small, this results in low luminance of the product.

FIG. 3 is a pixel circuit diagram of the conventional OLED display device. In FIG. 3, transistor T1 is a switching TFT (thin film transistor), transistor T2 is a driving TFT. The drain of transistor T1 is connected to a data line Vdata, the gate thereof is connected to the first scan line Scan1, the source thereof is connected to an end of the storage capacitor and the gate of the second transistor T2. When transistor T1 is open, data voltage Vdata is written in the gate of transistor T2 and stored in the storage capacitor. Afterwards, transistor T1 is closed; the gate of transistor T2 is connected to the source of transistor T1, the drain of transistor T2 is connected to power line VDD, the source of transistor T2 is connected to the anode of OLED, the voltage applied across the storage capacitor controls the electric current flowing through the OLED, thereby controlling the light emitting intensity of the OLED.

From the description above, as limited by the evaporation accuracy of OLED display device, the conventional OLED display device has small actual light emitting area and low aperture ratio, most pixel areas are not used. In the conventional OLED display device, the aperture ratio is less than 20%. As a result, the conventional OLED display device has low luminance, and it cannot satisfy the requirements of the user in some cases.

The above information disclosed in this Background section is only for enhancement of understanding of the background of the application and therefore it may contain information that does not form the prior art that is already known in this country to a person of ordinary skill in the art.

### SUMMARY OF DISCLOSURE

### Problem to be Solved

In the application, to prevent the problems in the conventional technology, the application discloses a dual-side OLED display which not only uses the display area effectively but also achieves dual-side display effect. The application also discloses a controlling device for controlling the dual-side display and a method for manufacturing the dual-side display.

### Technical Solution

A technical solution of the application discloses a dual-side display, including an OLED substrate, a package substrate located at opposite side of the OLED substrate and frit seal sandwiched between the OLED substrate and the package substrate. In the dual-side display, the package substrate is an electrophoresis membrane, the light-emitting area of the OLED device achieves OLED display, and the area that the OLED does not emit light achieves electrophoresis membrane display. The OLED emits light from bottom, the electrophoresis membrane displays from the top, the OLED and the electrophoresis membrane can display at the same time or separately.

OLED light emitting devices and active matrix TFTs are disposed at the OLED substrate.

The OLED substrate is made of rigid or flexible material.

The electrophoresis membrane is capable of achieving flexible display.

The disclosure further discloses a controlling device for controlling the dual-side display, including a first switching TFT (T1), a driving TFT (T2), a drain of the first switching TFT (T1) being connected to a data line, a gate of the first switching TFT (T1) is connected to a first scan line, a source of the first switching TFT (T1) is connected to an end of a storage capacitor and a gate of the driving TFT (T2), wherein, the controlling device further comprises a second switching TFT (T3), a drain of the second switching TFT (T3) is connected to the data line, a gate of the second switching TFT (T3) is connected to a second scan line, the source of the second switching TFT (T3) is connected to an electrode of the electrophoresis membrane,

The gate (T2) of the driving TFT is connected to the source of the first switching TFT (T1), the drain of the driving TFT is connected to the power line, the source of the driving TFT is connected to an anode of the OLED substrate.

When the first switching TFT (T1) is turned on, the voltage is written to the storage capacitor via the first switching TFT (T1). When the driving TFT (T2) is turned on, the electric current input by the power line flows through the OLED substrate to make the OLED substrate display. Namely, when only OLED display is needed, T1 is turned on first, voltage is written to the storage capacitor via the first switching TFT (T1), and then TFT T1 is turned off, and then TFT T2 is turned on, the OLED begins to emit light.

The electric current flowing through the OLED substrate is controlled by the data voltage.

When the first switching TFT (T1) is turned off and the second switching TFT (T3) is turned on, only the electrophoresis membrane displays, when the first switching TFT (T1) and the second switching TFT (T3) are turned on at the same time, the OLED substrate and the electrophoresis membrane display at the same time.

The first switching TFT (T1) and the second switching TFT (T3) shares a data line.

The disclosure further discloses method for manufacturing the dual-side display, wherein the method comprises the steps of: depositing a semi-conductor layer at a transparent substrate and patterning the semi-conductor layer; depositing a first insulating layer and a first metal layer on the patterned semi-conductor layer and patterning the first metal layer; depositing a second insulating layer on the patterned metal layer, and patterning the second insulating layer; then depositing the second metal layer and patterning the second metal layer; forming a flat layer at the surface of the patterned second metal layer and patterning the flat layer; depositing a pixel electrode layer at the surface of the flat layer, a first part of the pixel electrode layer is connected to a source of a driving TFT, and used as the anode of the OLED substrate, the second part of the pixel electrode layer is connected to a pixel electrode of the electrophoresis membrane and controls the display of the electrophoresis membrane; evaporating the OLED light emitting material and cathode material in sequence above the OLED substrate to form the OLED device; and packaging the OLED device with the electrophoresis membrane.

The substrate is a transparent rigid substrate or a transparent flexible substrate.

The semi-conductor layer is a A-Si (Amorphous Silicon), LTPS (Low Temperature Poly Silicon) or oxide.

The flat layer is formed by spin coating.

The first part of the pixel electrode layer and the second part of the pixel electrode layer are independent.

### Beneficial Effect

The dual-side display according to the application can effectively increase the light emitting area of the OLED, as well as the aperture ration and the display luminance of the OLED display panel, and achieves dual-side display to satisfy different requirements. Besides, in the application, the OLED display can be complementary with the electrophoresis membrane, therefore, it can make full use of light-emitting pixel area and obtain better light emitting effect.

It should be understood that, the foregoing general description and the following detailed description are exemplary and explanatory, and are intended to provide further explanation of the claimed disclosure.

### BRIEF DESCRIPTION OF THE DRAWINGS

The foregoing and other features and advantages of the disclosure will be apparent to those skilled in the art in view of the following detailed description, taken in conjunction with the accompanying drawings, in which.

FIG. 1 is a schematic sectional diagram showing a conventional OLED display device.

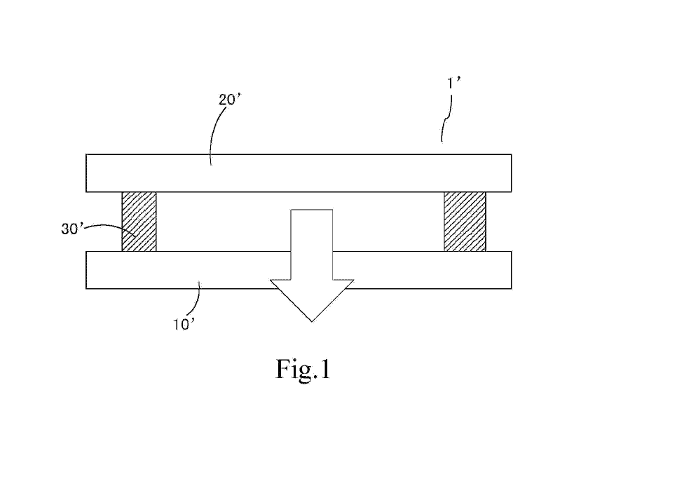

FIG. 2 is a schematic diagram showing a pixel plane in the conventional OLED display device in FIG. 1.

FIG. 3 is a pixel circuit diagram of the conventional OLED display device.

FIG. 4 is a schematic sectional diagram showing an OLED display device according to an embodiment of the application.

FIG. 5 is a schematic diagram showing a pixel plane in the OLED display device according to an embodiment of the application.

FIG. 6 is a pixel circuit diagram of the OLED display device according to an embodiment of the application.

FIG. 7 is a pixel sectional diagram showing the OLED display device according to an embodiment of the application.

### DETAILED DESCRIPTION

Exemplary embodiments of the application will now be described more fully with reference to the accompanying drawings.

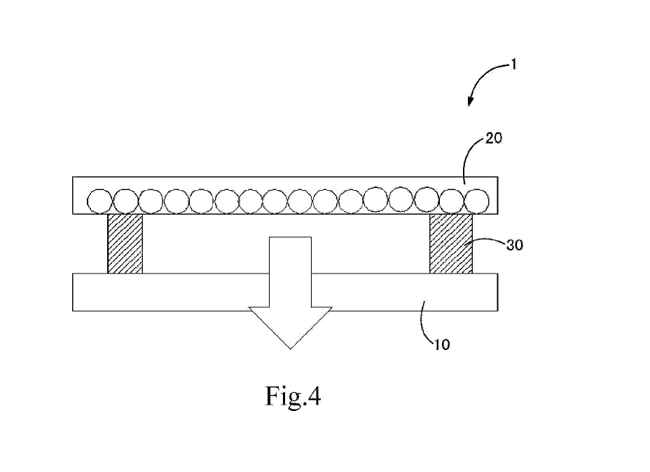

FIG. 4 is a schematic sectional diagram showing an OLED display device 1 according to an embodiment of the disclosure. As shown in FIG. 4, the OLED display device 1 according to an embodiment of the disclosure includes an OLED substrate 10, OLED light emitting devices and active matrix TFTs (thin film transistors) are disposed on the OLED substrate 10. The OLED substrate 10 can be made of rigid material or flexible material. The opposite side of the OLED substrate 10 is a package substrate, the package substrate according to an embodiment of the disclosure may be electrophoresis membrane 20. Frit seal 30 is disposed between the OLED substrate 10 and the electrophoresis membrane 20. The frit seal 30 is used to bond the OLED substrate 10 and the electrophoresis membrane 20 together.

The electrophoresis membrane 20 in the disclosure can not only be used as package material for packing the OLED substrate 10, but also achieves flexible display. The electrophoresis membrane 20 itself can display images, when voltage is applied across two ends of the electrophoresis membrane 20, positive charges and negative charges in the electrophoresis membrane capsule inside the electrophoresis membrane 20 move towards two directions, respectively, so as to achieve the function for displaying. The electrophoresis membrane 20 has bi-stable state which is an outstanding characteristic thereof. The electrophoresis membrane 20 may still display images even when the applied electric field is removed. In one case in practical application, when only displaying dynamic color image is needed, the OLED display is switched to, and when only displaying black-white image is needed, the electrophoresis membrane display is used only to save power. As a result, according to the application, the part of the electrophoresis membrane 20 that is located at the OLED display area is taken as packaging material, and the part of the electrophoresis membrane 20 that does not cover the OLED display area may be used as electrophoresis membrane display after voltage is applied across two ends thereof. As shown in the arrow in FIG. 4, according to an embodiment of the disclosure, the OLED display device may emit light from the bottom, namely the bottom surface of the OLED display device is a light-emitting surface, and the electrophoresis membrane 20 upon the OLED display device can also be used for display, therefore the dual-side display is achieved. For example, if only character display is needed, or only black-white image display is needed, the electrophoresis membrane 20 may be used to save power.

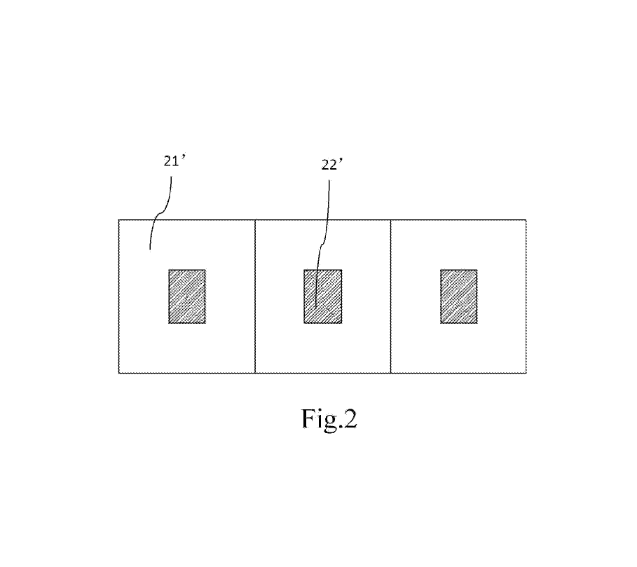

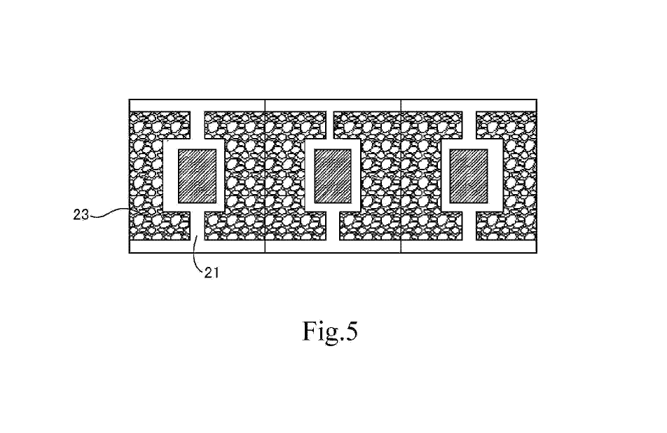

FIG. 5 is diagram schematic diagram showing a pixel plane in the OLED display device according to an embodiment of the disclosure. According to the OLED display device of the disclosure, a pixel layer 23 is added at the blank area 21, compared with the pixel plane diagram showing the conventional OLED display device in FIG. 2, the OLED display device in the disclosure makes full use of the pixel layer, and turns the area in the OLED display which cannot emit light to a pixel electrode layer of the electrophoresis membrane, the electrophoresis membrane display function is added on the basis that the OLED light emitting area is not reduced.

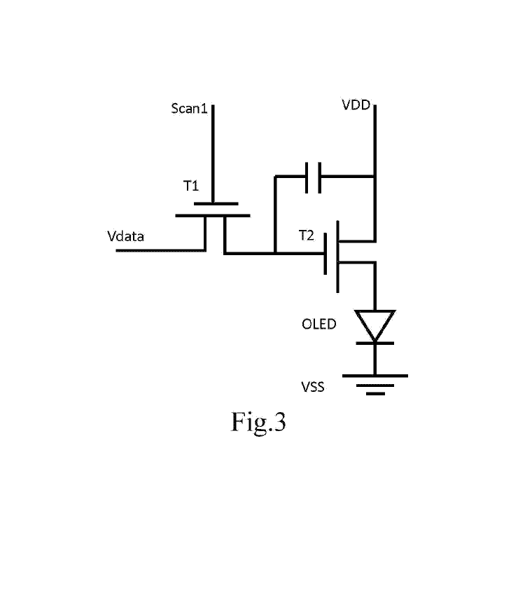

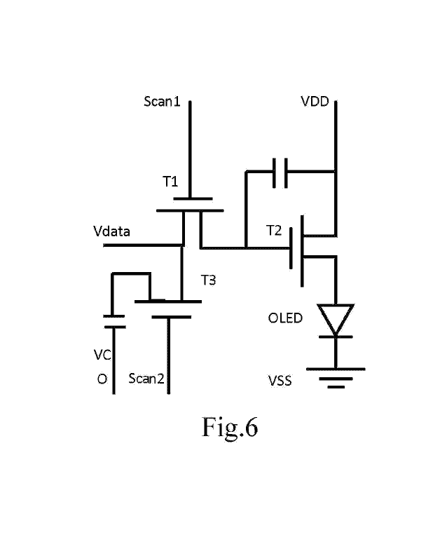

FIG. 6 is a pixel circuit diagram of the OLED display device according to an embodiment of the disclosure. Compared with the pixel circuit diagram in the conventional OLED display device in FIG. 3, the pixel circuit in the disclosure adds a switching TFT T3. The drain of the TFT T1 is connected to the data line Vdata, the gate of the TFT T1 is connected to the first scan line Scan1, and the source of the TFT T1 is connected to the gate of TFT T2. The gate of the TFT T2 is connected to the source of the TFT T1, the drain of the TFT T2 is connected to the power line VDD, the source of the TFT T2 is connected to the anode of the OLED. The drain of TFT T3 is connected to data line Vdata, the gate of TFT T3 is connected to the second scan line Scan2, the source of TFT T3 is connected to the electrode of electrophoresis membrane. When only OLED display is used, TFT T1 is on, the data voltage Vdata is written to the storage capacitor via the TFT T1. An end of the storage capacitor is connected to the gate of TFT T2, and the other end is connected to the power line VDD. When T2 is open, electric current inputted by the power line VDD flows through the OLED to make the OLED emit light, the electric current magnitude flowing through the OLED is determined by the magnitude of data line Vdata. Namely, only when OLED display is used, TFT T1 is on first, voltage is written to the storage capacitor via the first switching TFT (T1), and then T1 is off, and then TFT T2 is on, the OLED begins to emit light. When only the electrophoresis membrane display is used, the TFT T1 is in an off state, TFT T3 is on. When dual-side display is needed, both TFT T1 and TFT T3 are on, the OLED and electrophoresis membrane display at the same time.

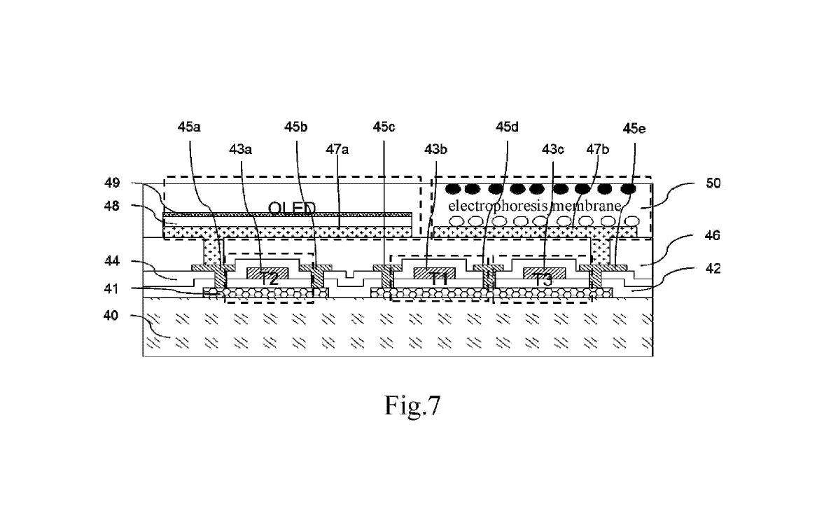

FIG. 7 is a pixel sectional diagram showing the OLED display device according to an embodiment of the disclosure. According to the embodiment, the OLED display device in the disclosure is manufactured in the following processes:

First, depositing a semi-conductor layer 41 on a glass substrate 40 and patterning the semi-conductor layer 41. To make the OLED emit light from the bottom, the substrate 40 may also be made of other transparent materials. The semi-conductor layer 41 maybe Amorphous Silicon (A-Si), low temperature poly-silicon (LTPS), oxide and so on. Afterwards, depositing a first insulating layer 42 and a first metal layer 43 in sequence on the patterned semi-conductor layer 41, and patterning the first metal layer 43, the first part 43a of the patterned first metal layer corresponds to the gate of TFT T2 in FIG. 6, the second part 43b of the patterned first metal layer corresponds to the gate of TFT T1 in FIG. 6, the third part 43c of the patterned first metal layer corresponds to the gate of the TFT T3 in FIG. 6. The gate of the first part 43a of the patterned first metal layer is connected to the source 45c of the TFT T1.

Afterwards, depositing a second insulating layer 44 at the patterned metal layer 43, and patterning the second insulating layer 44. The purpose of patterning the second insulating layer 44 is to form contact holes on the surface of the semi-conductor layer 41 and the surface of the first metal layer 43. The purpose of forming the contact hole is to achieve electric contact between the semi-conductor layer 41 and the second metal layer 45, and between the first metal layer 43 and the second metal layer 45. Afterwards, depositing the second metal layer 45 and patterning the second metal layer 45, the fourth part 45d of the patterned second metal layer corresponds to the data line Vdata in FIG. 6, TFT T1 and TFT T3 share a data line Vdata. The first part 45a of the patterned second metal layer corresponds to the source of the TFT T2 in FIG. 6, namely the anode of the OLED. The source of T2 is connected to the pixel electrode 47a of OLED, the second part 45b of the patterned second metal layer corresponds to the power line VDD in FIG. 6, and the third part 45c of the patterned second metal layer corresponds to the source of TFT T1 in FIG. 6, the source 45c of T1 is connected to the gate of TFT T2, the fifth part 45e of the pattered second metal layer corresponds to the source of TFT T3 in FIG. 6, namely connected to the pixel electrode 47a of the electrophoresis membrane. The surface of the patterned second metal layer 45 is formed with a flat layer 46 with spin coating method and the flat layer 46 is patterned, the flat layer may be used as an OC layer for flatting. A pixel electrode layer 47 is deposited on the surface of the flat layer 46, the first part 47a of the pixel electrode layer is connected to the source of the TFT T2 and used as the anode of the OLED, the second part 47b of the pixel electrode layer is connected to the pixel electrode of the electrophoresis membrane, namely the source of the TFT T3, the first part 47a of the pixel electrode layer is independent with the second part 47b of the pixel electrode layer. Afterwards, an OLED light emitting material and cathode material are deposited on the OLED, and the OLED device is formed. Afterwards the OLED device is packaged with electrophoresis membrane, employing the pixel electrode namely the second part 47b of the pixel electrode layer to control the display of the electrophoresis membrane.

TFT T1 and TFT T3 share a data line 45d. When the gate 43c of the TFT T3 is applied with voltage, TFT T3 is conducted, and electric current flows through the channel, data line voltage Vdata is written to the pixel electrode 47b to generate voltage difference between two sides of the electrophoresis membrane 50. Under the effect of the voltage difference, the positive particle capsule and negative particle capsule of the electrophoresis membrane 50 move towards opposite direction to achieve electrophoresis membrane display. The source 45c of TFT T1 is connected to the gate 43a of the TFT T2 (not shown), and when the TFT T1 is conducted, the voltage of the data line 45d is written to the gate of the TFT T2 and stored in the capacitor (not shown) between the gate 43a in FIG. 4 and of the power line VDD (reference numeral 45b in FIG. 7), the magnitude of voltage stored in the capacitor controls the on/off state of TFT T2, when the TFT T2 is on, the electric current path is from the power line VDD (reference numeral 45b in FIG. 7) to the source 45a, and then pass the OLED device to achieve OLED displaying. The magnitude of the electric current is relative to the voltage stored in the capacitor, and the luminance of the OLED material 48 is relative to the electric current flowing through the OLED device. When the TFT T1 and TFT T3 are on at the same time, the electrophoresis membrane and the OLED display at the same time.

The operating process of the dual-side display in the embodiment shown in FIG. 7 is described hereinbelow: when only OLED displays, the TFT T1 is turned on first, the voltage is written to the storage capacitor via the TFT T1, then T1 is turned off, and TFT T2 is turned on, the light emitted by the OLED is from the bottom of the transparent substrate. When only the electrophoresis membrane displays, TFT T1 is in an off state, TFT T3 is on, the electrophoresis membrane at the above is used to display. When dual side display is needed, TFT T1 and TFT T3 are in an on state at the same time, as a result, the electrophoresis membrane and the OLED display at the same time.

According to the OLED display device in the disclosure, since the electrophoresis membrane is used as the package substrate, the OLED display device not only achieves dual display, but also adds a pixel layer due to the electrophoresis membrane, which increases the aperture area as well as the display luminance of the OLED.

Exemplary embodiments have been specifically shown and described as above. It will be appreciated by those skilled in the art that the application is not limited the disclosed embodiments; rather, all suitable modifications and equivalent which come within the spirit and scope of the appended claims are intended to fall within the scope of the application.

What is claimed is:

1. A dual-side display having an OLED substrate, a package substrate located at opposite side of the OLED substrate and frit seal sandwiched between the OLED substrate and the package substrate, wherein the improvements comprise:
the package substrate is an electrophoresis membrane, the electrophoresis membrane located on a display region of the OLED substrate is partially formed as a packaging material, and the electrophoresis membrane not located on the display region of the OLED substrate is partially formed as a first display surface of the dual-side display, the display region of the OLED substrate is formed as a second display surface opposite to the first display surface of the dual-side display.

2. The dual-side display according to claim 1, wherein the OLED substrate and the electrophoresis membrane are configured to display at the same time or separately.

3. The dual-side display according to claim 1, wherein OLED light emitting devices and active matrix TFTs are disposed at the OLED substrate.

4. The dual-side display according to claim 1, wherein the OLED substrate is made of rigid or flexible material.

5. The dual-side display according to claim 1, wherein the electrophoresis membrane is configured to achieve flexible display.

6. The dual-side display according to claim 1 further comprising a controlling device, the controlling device having:
a first switching TFT (T1), a drain of the first switching TFT (T1) being connected to a data line, a gate of the first switching TFT (T1) is connected to a first scan line, a source of the first switching TFT (T1) is connected to an end of a storage capacitor;
a driving TFT (T2), a gate of the driving TFT (T2) is connected to the source of the first switching TFT (T1), the drain of the driving TFT (T2) is connected to the power line, the source of the driving TFT (T2) is connected to an anode of the OLED substrate; and
a second switching TFT (T3), a drain of the second switching TFT (T3) is connected to a data line, a gate of the second switching TFT (T3) is connected to a second scan line, the source of the second switching TFT (T3) is connected to an electrode of the electrophoresis membrane.

7. The dual-side display according to claim 6, wherein when the first switching TFT (T1) is turned on, the voltage is written to the storage capacitor via the first switching TFT (T1), then the first switching TFT (T1) is turned off, the driving TFT (T2) is turned on, the electric current input by the power line flows through the OLED substrate to make the OLED substrate display.

8. The dual-side display according to claim 7, wherein the electric current flowing through the OLED substrate is controlled by the data voltage.

9. The dual-side display according to claim 7, wherein when the first switching TFT (T1) is turned off and the second switching TFT (T3) is turned on, only the electrophoresis membrane displays, when the first switching TFT (T1) and the second switching TFT (T3) are turned on at the same time, the OLED substrate and the electrophoresis membrane display at the same time.

10. The dual-side display according to claim 6, wherein the first switching TFT (T1) and the second switching TFT (T3) shares a data line.

11. A method for manufacturing the dual-side display according to claim 1, wherein the method comprises the steps of:
depositing a semi-conductor layer at a transparent substrate and patterning the semi-conductor layer;
depositing a first insulating layer and a first metal layer on the patterned semi-conductor layer and patterning the first metal layer;
depositing a second insulating layer on the patterned metal layer, and patterning the second insulating layer;
and then depositing the second metal layer and patterning the second metal layer;
forming a flat layer at the surface of the patterned second metal layer and patterning the flat layer;
depositing a pixel electrode layer at the surface of the flat layer, a first part of the pixel electrode layer is connected to a source of a driving TFT and used as the anode of the OLED substrate, the second part of the pixel electrode layer is connected to a pixel electrode of the electrophoresis membrane to control the display of the electrophoresis membrane;
evaporating the OLED light emitting material and cathode material above the OLED substrate to form the OLED device; and
packaging the OLED device with the electrophoresis membrane.

12. The method for manufacturing the dual-side display according to claim 11, wherein the transparent substrate is a glass substrate.

13. The method for manufacturing the dual-side display according to claim 11, wherein the semi-conductor layer is an Amorphous Silicon, Low Temperature Poly Silicon or oxide.

14. The method for manufacturing the dual-side display according to claim 11, wherein the flat layer is formed by spin coating.

15. The method for manufacturing the dual-side display according to claim 11, wherein the first part of the pixel electrode layer and the second part of the pixel electrode layer are independent.
